(19) United States
(12) Patent Application Publication
(10) Pub. No.: US 2019/0311978 A1
(43) Pub. Date: Oct. 10, 2019

(54) COMPOSITE STACKED INTERCONNECTS FOR HIGH-SPEED APPLICATIONS AND METHODS OF ASSEMBLING SAME

(71) Applicant: Intel Corporation, Santa Clara, CA (US)

(72) Inventors: Bok Eng Cheah, Bukit Gambir (MY); Ping Ping Ooi, Butterworth (MY); Shaw Fong Wong, Penang (MY); Jackson Chung Peng Kong, Tanjung Tokong (MY); Hungying Lo, Folsom, CA (US)

(21) Appl. No.: 16/280,850

(22) Filed: Feb. 20, 2019

(30) Foreign Application Priority Data
Apr. 4, 2018 (MY) PI 2018701348

(51) Int. Cl. H01L 23/498; H05K 1/18; H01L 23/00; H01L 25/16; H01L 21/48; H05K 3/34

(52) U.S. Cl. CPC H01L 23/49816; H01L 23/3128; H05K 1/181; H01L 24/16; H01L 25/16; H01L 21/4853; H01L 24/81; H05K 3/3494; H05K 2201/10378; H05K 2201/10734; H05K 2201/10674; H01L 2224/16227; H01L 2924/19105; H01L 23/49822; H01L 23/49838

(57) ABSTRACT

A semiconductor package substrate includes a composite and stacked vertical interconnect on a land side of the substrate. The composite and stacked vertical interconnect includes a smaller contact end against the semiconductor package substrate, and a larger contact end for board mounting.

### PRIORITY APPLICATION

This application claims the benefit of priority to Malaysian Application Serial Number PI 2018701348, filed Apr. 4, 2018, which is incorporated herein by reference in its entirety.

### FIELD

This disclosure relates to land-side interconnects for semiconductor package apparatus.

### BACKGROUND

Semiconductive device miniaturization during packaging requires high-speed interconnections.

### BRIEF DESCRIPTION OF THE DRAWINGS

Disclosed embodiments are illustrated by way of example, and not by way of limitation, in the figures of the accompanying drawings where like reference numerals may refer to similar elements, in which:

FIG. 1A is a cross-section elevation of a semiconductor device 100 during assembly, with a composite and stacked vertical interconnect according to an embodiment;

FIG. 1B is a detail section of the land-side trace depicted in FIG. 1A according to an embodiment:

FIG. 1C is a detail view of the composite and stacked vertical interconnect as it contacts the land-side trace according to an embodiment;

FIG. 1D is a detail view of the composite and stacked vertical interconnect depicted in FIG. 1C after reflowing and bonding to the land 150 according to an embodiment;

FIG. 2A is a cross-section elevation of a semiconductor device package with a composite and stacked vertical interconnect according to an embodiment:

FIG. 2D is a detail view of the composite and stacked vertical interconnect depicted in FIG. 2A after reflowing and bonding to the land 250 according to an embodiment. Items 2B and 2C are omitted:

FIG. 3 is a cross-section elevation of semiconductor device package with a composite and stacked vertical interconnect and a land-side passive device according to an embodiment;

FIG. 4 is a cross-section elevation of a semiconductor device package with composite and stacked vertical-interconnects according to an embodiment;

FIG. 5 is a process flow diagram according to several embodiments; and

FIG. 6 is included to show an example of a higher-level device application for the disclosed embodiments.

### DETAILED DESCRIPTION

Semiconductor device packages are assembled to improve signal integrity in the range such as 56 GHz for fifth-generation (5G) interconnections in the 60 GHz range. Channel impedance discontinuities and electrical insertion loss are addressed by using composite stacked vertical interconnects on the land side of the semiconductor device packages. Small-contact-area composite and stacked vertical interconnects are also located near terminal ends of land-side traces, to increase interconnect density.

In an embodiment, a composite and stacked vertical interconnect is processed from a double-spheroidal assembly, that shows improved insertion loss of −4.9 decibel (dB) compared to −8.5 dB at 56 GHz with a channel length of about 15 mm for a second-level interconnect on the land side of a semiconductor package substrate. In an embodiment, a composite and stacked vertical interconnect is processed from a spheroidal and rectangular assembly, that shows improved insertion loss of −4.9 decibel (dB) compared to −8.5 dB at 56 GHz with a channel length of about 15 mm for a second-level interconnect on the land side of a semiconductor package substrate.

The land-side composite and stacked vertical interconnects are second-level interconnects as understood where a semiconductive device is first-level connected to the semiconductor package substrate on the die side, and the second-level interconnect provides a stand-off height that makes both a useful small contact area on a land side trace, and a useful larger contact area for contacting a board such as a motherboard.

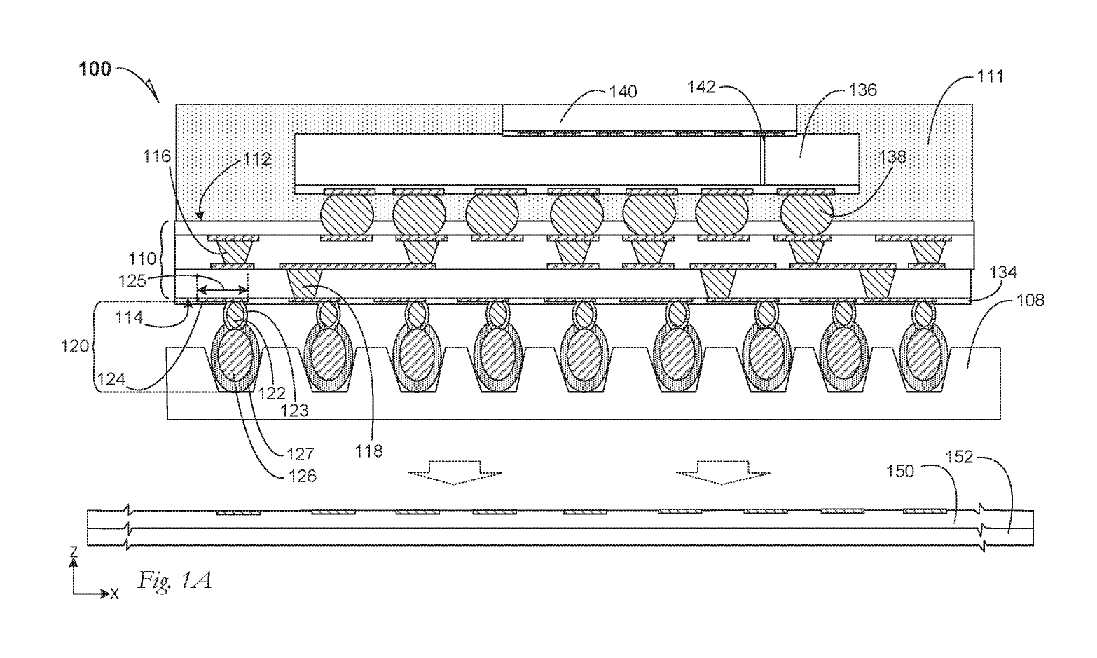

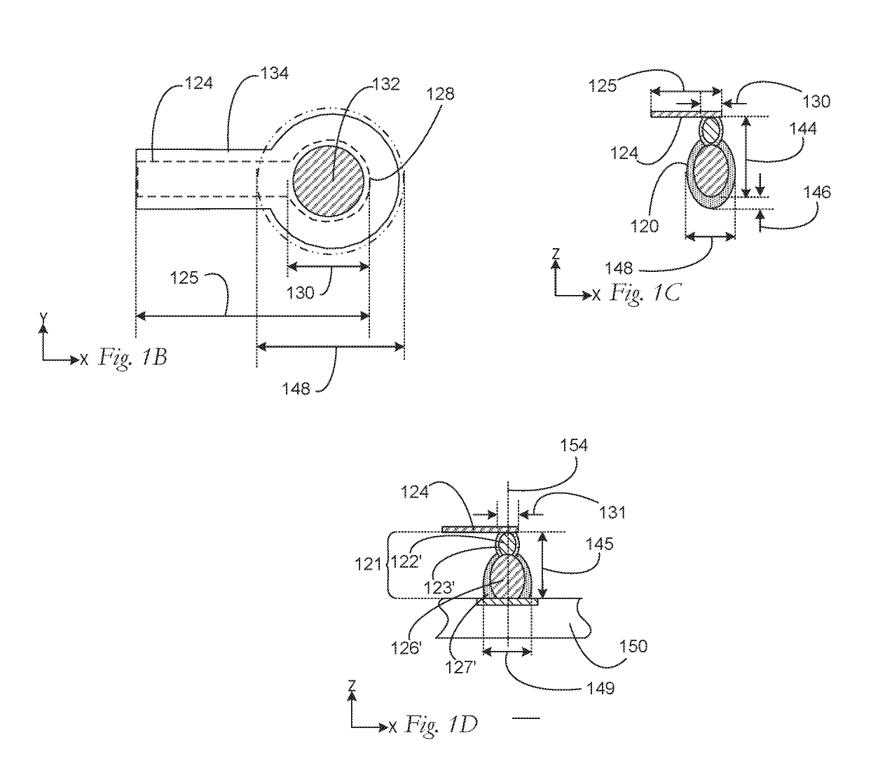

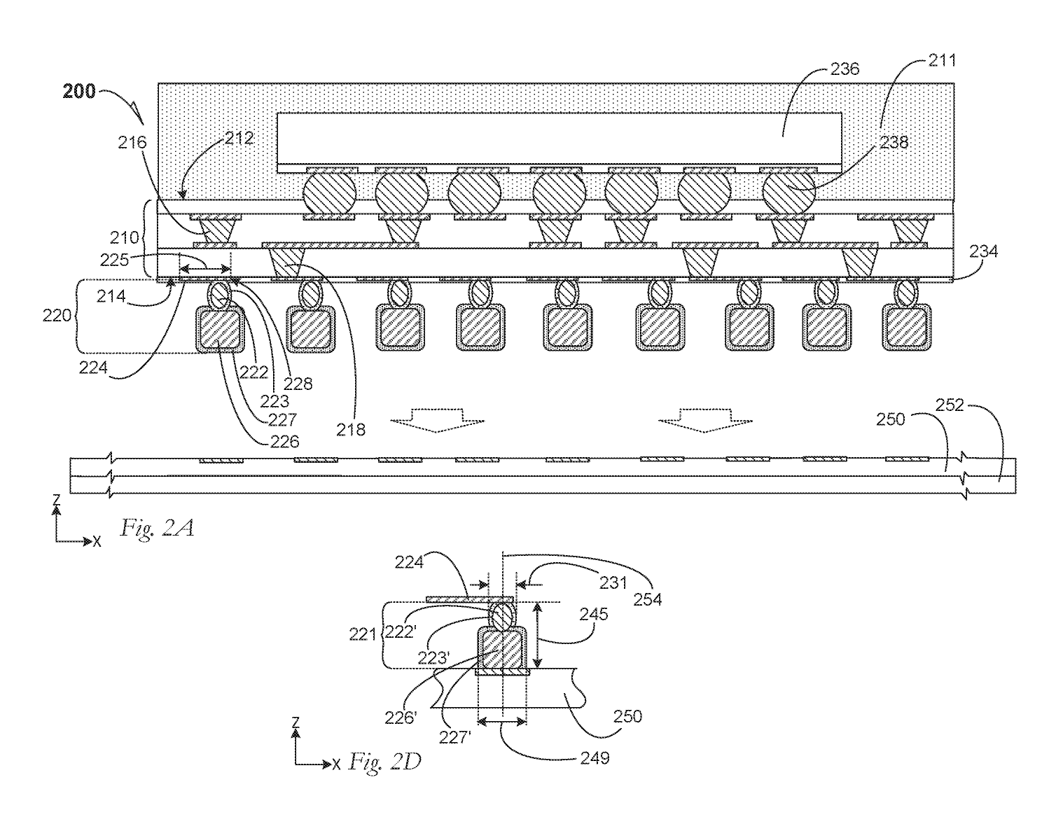

FIG. 1A is a cross-section elevation of a semiconductor device package 100 during assembly, with a composite and stacked vertical interconnect 120 according to an embodiment. In an embodiment, a semiconductor package substrate 110 includes a die side 112 and a land side 114. As illustrated, the semiconductor package substrate 110 is coreless and it has three layers with interlayer interconnects 116 and 118, where the interlayer interconnect 116 communicates to the die side 112 and the interlayer interconnect 118 communicates to the land side 114. In an embodiment, a semiconductor package substrate has a substrate core that uses a composite and stacked vertical interconnect.

As illustrated the second-level interconnect 120 is part of a composite and stacked vertical interconnect array 120 that is configured across the land side 114 of the semiconductor package substrate 110. Also as illustrated, the composite and stacked vertical interconnect array 120 is substantially uniformly distributed across the X-Y plane of the of the semiconductor package substrate 110 at the land side 114. By “substantially uniformly distributed” it is meant that an interconnect pitch between any two adjacent composite and stacked vertical interconnects, is within a useful average pitch-deviation standard, beginning at given edge of the semiconductor package substrate 110, and ending at the opposite edge.

In an embodiment, a second-level interconnect 120 is assembled from a first interconnect component that includes a first core material 122 such as copper, and a first shell material 123 such as solder. Further the second-level interconnect 120 includes a second interconnect component that includes a second core material 126 such as copper, and a second shell material 127 such as solder. The composite and stacked vertical interconnect 120 contacts a trace 124 on the land side 114 of the semiconductor package substrate 110. In an embodiment, a dielectric layer e.g., solder resist layer 134 extends over the trace 124 to electrically insulate the trace 124 and the composite and stacked vertical interconnects 120.

In an embodiment, a composite and stacked vertical interconnect 120 contacts the land-side trace 124 near a terminal end 128 of the trace 124 (see FIG. 1B). Additionally, the composite and stacked vertical interconnect 120 includes a first diameter 130 and a second a diameter 148 that is projected onto the trace 124 (see FIG. 1B).

In an embodiment, the composite and stacked vertical interconnect 120 is formed by first assembling the first core 122 and first shell 123 to the trace 124 near the terminal end 128 (see FIG. 1B) of the trace 124. Thereafter, the second core 126 and second shell 127 are assembled to the first core 122 and first shell 123 such as by pre-placing the second core and shell 126 and 127 in a tray 108, and contacting the first core and shell 122 and 123 to the second core and shell 126 and 127 until useful adhesion is achieved, and thereafter, by removing the tray 108. In an embodiment, useful adhesion is at the onset of reflow at commencement of the liquidus state of the respective first and second shells 123 and 127.

In an embodiment, the die side 112 supports a first semiconductive device 136. In an embodiment, the first semiconductive device 136 is flip-chip mounted on the die side 112 through a ball array, one of which is indicated with reference number 138, as illustrated. In an embodiment, an overmolding material 111 contacts the die side 112 and at least partially encapsulates the first semiconductive device 136. In an embodiment, although only one semiconductive device 136 is depicted, the die side 112 supports two semiconductive devices including the first semiconductive device 136 as flip-chip mounted, and a subsequent semiconductive device that is also flip-chip mounted on the ball array 138. For example, the first semiconductive device 136 is flip-chip mounted side-by-side with a subsequent semiconductive device (not illustrated) that is also flip-chip mounted on the die side 112.

In an embodiment, the first semiconductive device 136 supports a subsequent semi conductive device 140 that is die-stacked above the first semiconductive device 136. In an embodiment, the die-stacked subsequent semiconductive device 140 communicates to the first semiconductive device 136 by a through-silicon via (TSV) 142.

FIG. 1B is a detail section of the land-side trace 124 depicted in FIG. 1A according to an embodiment. The land-side trace 124 is contacted by the first core 122 and first shell 123 through an opening of the dielectric layer (e.g., solder resist layer) 134, and the land-side trace 124 has a trace length 125.

The land-side trace 124 includes the terminal end 128 near where the composite and stacked vertical interconnect 120 makes contact. In an embodiment, the terminal end 128 has a characteristic dimension 130 that is larger than the width of the trace width (along the Y-dimension), in a range from about 1.2 times to about 3 times larger. In an embodiment, the terminal end 128 is circular. In an embodiment and as illustrated, the terminal end 128 has a first characteristic dimension 130, in this case a diameter as that largest dimension because the terminal end 128 is circular. In an embodiment, an exposed portion 132 of the terminal end 128 is circular. In an embodiment, the characteristic dimension 130 is the larger axis of an oval exposed portion of a trace at the terminal end 128. In an embodiment, the characteristic dimension 130 is the larger axis of a rectangular exposed portion of a trace at the terminal end 128, for example, where the exposed portion had a bond-finger form factor although the trace 124 is not expanded at the terminal end 128.

In an embodiment, the exposed portion 132 is seen through the dielectric layer e.g., solder resist layer 134 that is used to electrically insulate the trace 124, and the remainder of the trace 124 is depicted in ghosted lines. The dielectric layer 134 obscures a portion of the terminal end 128 as well as most of the trace 124.

FIG. 1C is a detail view of the composite and stacked vertical interconnect 120 as it contacts the land-side trace 124 according to an embodiment. The composite and stacked vertical interconnect 120 is quantified in part by a composite and stacked height 144, and a surplus height 146 that is flattened and that at least partially disappears after reflow bonding to a land 150 (see FIG. 1A) such as a motherboard. The composite and stacked height 144, represents an electrical-bump standoff height that results after bonding to a land such as the land 150 depicted in FIG. 1A.

In an embodiment, the land 150 is a printed-wiring board 150 with an external shell 152 that provides at least one of structural and electrical-insulative qualities for the board 150.

In an embodiment, the composite and stacked vertical interconnect 120 can be quantified in form factor by a first form factor, which is the composite and stacked height 144, divided by the diameter 130 of the exposed portion 132 of the terminal end 128. In an embodiment, the composite and stacked vertical interconnect 120 can be quantified in form factor by a second form factor, which is the composite and stacked height 144, divided by a second diameter 148 of the second core and shell 126 and 127. In an embodiment, the exposed portion 132 measures seven units and the and the second diameter measures 13 units, where the stacked height 144 is 29 units. With these measurements, the first form factor is 29 divided by seven, and the second form factor is 29 divided by 13. In an embodiment, the first form factor is in a range from 1.5 to 4.5. In an embodiment, the second form factor is in a range from 1.1 to 2.5. In each embodiment, the form factor includes a lateral dimension that is in the X-Y plane and the form factor includes at least an X-direction measurement and a Z-direction measurement.

FIG. 1D is a detail view of the composite and stacked vertical interconnect 120 depicted in FIG. 1C after reflowing and bonding to the land 150 according to an embodiment. The composite and stacked vertical interconnect 120 depicted in FIG. 1C has been reflowed to a composite and stacked vertical interconnect 121 and the stacked height 144 depicted in FIG. 1C is reflowed to a stacked height 145. In an embodiment, the stacked height 145 is less than the stacked height 144. Further, the characteristic dimension 130 depicted in FIG. 1C has been changed to a reflowed characteristic dimension 131, and the characteristic dimension 131 is larger than the characteristic dimension 130 due to reflow processing. Further, the characteristic dimension 148 depicted in FIG. 1C has been changed to a reflowed characteristic dimension 149, and the reflowed characteristic dimension 149 is larger than the characteristic dimension 148 due to reflow processing. In any event, the overall form factor of the reflowed stacked height 145, remains above 1. In an embodiment, the overall form factor, measured by the relative lengths of items 145 and 149 is in a range from 1.05 to 1.2. In an embodiment, the overall form factor, measured by the relative lengths of items 145 and 131 is in a range from 1.5 to 3.6.

In an embodiment, reflow causes some or all the shell solder materials 123 and 127 to blend into the respective core copper materials 122 and 126. In an embodiment, chemical analysis of the composite and stacked vertical interconnect 121 shows a solder-rich zone 123′ and a copper-rich zone 122′ where the first core 122 and first shell 123 have partially blended as depicted in FIG. 1A. Similarly in an embodiment, chemical analysis shows a solder-rich zone 127′ and a copper-rich zone 126′ where the second core 126 and second shell 127 also as depicted in FIG. 1A have partially blended. In an embodiment, no solder materials are depicted at a symmetry line 154 and for 10 percent of the lateral (X and Y directions) distances 131 and 149, respectively on either side of the symmetry line 154. In an embodiment, some intermetallic compounds (not illustrated) form as a result of solder and copper reflowing, including in an embodiment, at a location that intersects the symmetry line 154.

FIG. 2A is a cross-section elevation of a semiconductor device package 200 with a composite and stacked vertical interconnect 220 according to an embodiment. In an embodiment, a semiconductor package substrate 210 includes a die side 212 and a land side 214. As illustrated, the semiconductor package substrate 210 is coreless and it has three layers with interlayer interconnects 216 and 218, where the interlayer interconnect 216 communicates to the die side 212 and the interlayer interconnect 218 communicates to the land side 214. In an embodiment, a semiconductor package substrate has a substrate core that uses a composite and stacked vertical interconnect.

As illustrated the second-level interconnect 220 is part of a composite and stacked vertical interconnect array 220 that is configured across the land side 214 of the semiconductor package substrate 210. Also as illustrated, the composite and stacked vertical interconnect array 220 is substantially uniformly distributed across the X-Y plane of the of the semiconductor package substrate 210 at the land side 214. By “substantially uniformly distributed” it is meant that an interconnect pitch between any two adjacent composite and stacked vertical interconnects, is within a useful average pitch-deviation standard, beginning at given edge of the semiconductor package substrate 210, and ending at the opposite edge.

In an embodiment, the composite and stacked vertical interconnect 220 is a second-level interconnect 220 that is assembled from a first interconnect component 222 that includes a first core material 222 such as copper, and a first shell material 223 such as solder. Further the second-level interconnect 220 includes a second interconnect component 226 that includes a second core material 226 such as copper, and a second shell material 227 such as solder. The composite and stacked vertical interconnect 220 contacts a trace 224 on the land side 214 of the semiconductor package substrate 210. As illustrated, the second core 226 and second shell 227 have a composite rectangular form factor, whereas the first core 222 and first shell 223 have a composite curvilinear form factor.

In an embodiment, the composite and stacked vertical interconnect 220 contacts the land-side trace 224 near a terminal end 228 of the trace 224.

In an embodiment, the composite and stacked vertical interconnect 220 is formed by first assembling the first core 222 and first shell 223 to the trace 224 near the terminal end 228 of the trace 224. Thereafter, the second core 226 and second shell 227 are assembled to the first core 222 and first shell 223 such as by pre-placing the second core and shell 226 and 227 in a tray analogous to the tray 108 depicted in FIG. 1A, and by contacting the first core and shell 222 and 223 to the second core and shell 226 and 227 until useful adhesion is achieved, and thereafter, by removing the tray.

In an embodiment, the die side 212 supports a first semiconductive device 236. In an embodiment, the first semiconductive device 236 is flip-chip mounted on the die side 212 through a ball array, one of which is indicated with reference number 238, as illustrated. In an embodiment, an overmolding material 211 contacts the die side 212 and at least partially encapsulates the first semiconductive device 236. In an embodiment, although only one semiconductive device 236 is depicted, the die side 212 supports two semiconductive devices including the first semiconductive device 236 as flip-chip mounted, and a subsequent semiconductive device that is also flip-chip mounted on the ball array 238. For example, the first semiconductive device 236 is flip-chip mounted side-by-side with a subsequent semiconductive device (not illustrated) that is also flip-chip mounted on the die side 212.

As indicated by two directional arrows, the composite and stacked vertical interconnect 220 is being seated on a land 250 such as a motherboard 250, that may have an external shell 252 in an embodiment.

FIG. 2D is a detail view of the composite and stacked vertical interconnect 220 depicted in FIG. 2A after reflowing and bonding to the land 250 according to an embodiment. Items 2B and 2C are omitted.

The composite and stacked vertical interconnect 220 depicted in FIG. 2A has been reflowed to a composite and stacked vertical interconnect 221 and a reflowed stacked height 245 has resulted. A reflowed first characteristic dimension 231 describes the first interconnect components 222 and 223, and reflowed second characteristic dimension 249 describes the second interconnect components 226 and 227, as presented in FIG. 2A.

In an embodiment, reflow causes some or all the shell solder materials 223 and 227 to blend into the respective core copper materials 222 and 226. In an embodiment, chemical analysis of the composite and stacked vertical interconnect 221 shows a solder-rich zone 223′ and a copper-rich zone 222′ where the first core 222 and first shell 223 have partially blended as were depicted in FIG. 2A. Similarly in an embodiment, chemical analysis shows a solder-rich zone 227′ and a copper-rich zone 226′ where the second core 226 and second shell 227 also as depicted in FIG. 2A have partially blended. In an embodiment, no solder materials are depicted at a symmetry line 254 and for 10 percent of the lateral (X and Y directions) distances 231 and 249, respective on either side of the symmetry line 254. In an embodiment, some intermetallic compounds (not illustrated) form as a result of solder and copper reflowing, including in an embodiment, at a location that intersects the symmetry line 254.

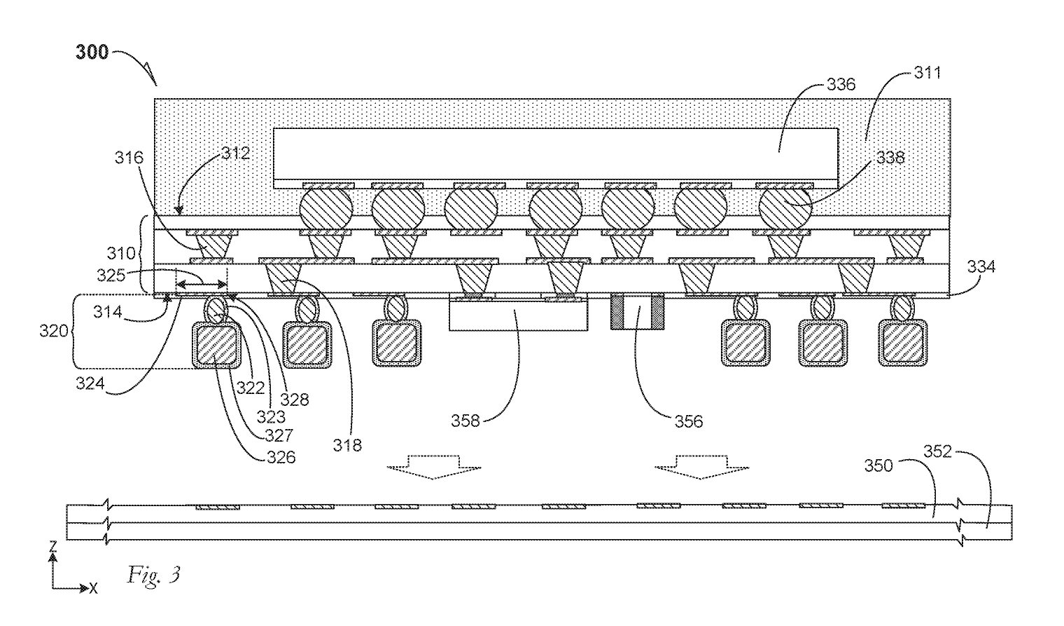

FIG. 3 is a cross-section elevation of semiconductor device package 300 with a composite and stacked vertical interconnect 320 and a land-side passive device 356 according to an embodiment. In an embodiment, a semiconductor package substrate 310 includes a die side 312 and a land side 314, and a land-side passive 356 is mounted on the land side 314. As illustrated, the semiconductor package substrate 310 is coreless and it has three layers with interlayer interconnects 316 and 318, where the interlayer interconnect 316 communicates to the die side 312 and the interlayer interconnect 318 communicates to the land side 314.

As illustrated the second-level interconnect 320 is part of a composite and stacked vertical interconnect array 320 that is configured across the land side 314 of the semiconductor package substrate 310. Also as illustrated, the composite and stacked vertical interconnect array 320 is substantially uniformly distributed across the X-Y plane of the of the semiconductor package substrate 310 at the land side 314, with an open space that accommodates at least one of the passive device 356 and a hanging semiconductive device 358. By “substantially uniformly distributed” it is meant that an interconnect pitch between any two adjacent composite and stacked vertical interconnects, is within a useful average pitch-deviation standard, beginning at given edge of the semiconductor package substrate 310, and ending at the opposite edge, except where the two given composite and stacked vertical interconnects 320 are adjacent across the open space.

In an embodiment, the composite and stacked vertical interconnect 320 contacts a land-side trace 324 near a terminal end 328 of the trace 324. In an embodiment, the land-side trace 324 has a trace length 325.

Processing to seat the passives 356 on the land side 314 is done by a pick-and-place technique. In an embodiment, the passive device 356 has a vertical (Z-direction) measurement of 330 micrometer (μm). In an embodiment, the passive 356 is a capacitor. In an embodiment, the passive 356 is an inductor. In an embodiment, the passive 356 is a resistor. In an embodiment, the passive 356 is one of a plurality of passives that are mounted on the land side 314.

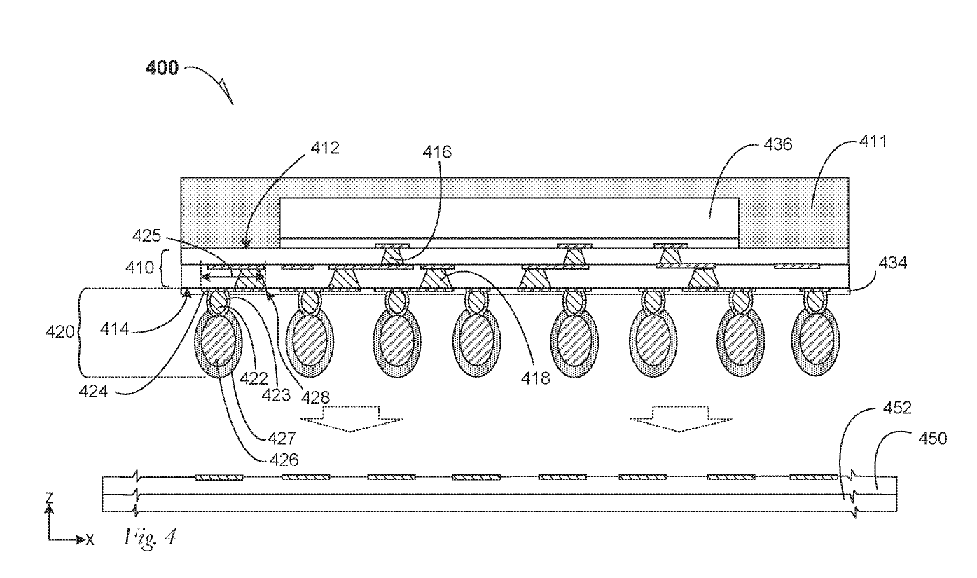

In an embodiment, a hanging semiconductive device 358 is “opossum” mounted on the land side 314 as the total standoff height of the composite and stacked vertical interconnect 320 provides sufficient clearance for the hanging semiconductive device 358. It is now understood that a hanging semiconductive device is applicable to any land side, such as the land sides 114 and 214, as well as a land side 414 to be further illustrated and described in FIG. 4. Further, it is now understood that a passive device such as the passive device 356 depicted in FIG. 3 is applicable to any land side, such as the land sides 114 and 214, as well as the land side 414 to be further illustrated and described in FIG. 4.

In an embodiment, the die side 312 supports a first semiconductive device 336. In an embodiment, the first semiconductive device 336 is flip-chip mounted on the die side 312 through a ball array, one of which is indicated with reference number 338, as illustrated. In an embodiment, an overmolding material 311 contacts the die side 312 and at least partially encapsulates the first semiconductive device 336. In an embodiment, although only one semiconductive device 336 is depicted, the die side 312 supports two semiconductive devices including the first semi conductive device 336 as flip-chip mounted, and a subsequent semiconductive device that is also flip-chip mounted on the ball array 338. For example, the first semi conductive device 336 is flip-chip mounted side-by-side with a subsequent semiconductive device (not illustrated) that is also flip-chip mounted on the die side 312.

In an embodiment, the first semiconductive device 336 on the die side 312 is a logic processor and the hanging semiconductive device 358 is a radio-frequency device such as a global-positioning system (GPS). In an embodiment, the hanging semiconductive device 358 is a baseband processor. In an embodiment, the hanging semiconductive device 358 is a memory die.

In an embodiment, the first semi conductive device 336 is coupled to and supports a subsequent semiconductive device similar to the subsequent semiconductive device 140 depicted in FIG. 1A.

In an embodiment, a land 350 is a printed-wiring board 350 with an external shell 352 that provides at least one of structural and electrical-insulative qualities for the board 350.

In an embodiment, the composite and stacked vertical interconnect 320 can be quantified in form factor similar to the form-factor parameters described for the composite and stacked vertical interconnect 221 depicted in FIG. 2D.

In an embodiment, reflow causes some or all the shell solder materials 323 and 327 to blend into the respective core copper materials 322 and 326. In an embodiment, chemical analysis of the composite and stacked vertical interconnect 321 shows a solder-rich and copper-rich zones that are analogous to the solder-rich zone 223′ and the copper-rich zone 222′ depicted in FIG. 2D, where the first core 322 and first shell 323 have partially blended as are depicted in FIG. 3. Similarly in an embodiment, chemical analysis shows solder-rich and copper-rich zones that analogous to the solder-rich zone 227′ and the copper-rich zone 226′ depicted in FIG. 2D, where the second core 326 and second shell 327 also as depicted in FIG. 3 have partially blended.

FIG. 4 is a cross-section elevation of a semiconductor device package 400 with composite and stacked vertical-interconnects according to an embodiment. In an embodiment, a semiconductor package substrate 410 includes a die side 412 and a land side 414. As illustrated, the semiconductor package substrate 410 is coreless and it has two layers with interlayer interconnects 416 and 418, where the interlayer interconnect 416 communicates to the die side 412 and the interlayer interconnect 418 communicates to the land side 414.

As illustrated the second-level interconnect 420 is part of a composite and stacked vertical interconnect array 420 that is configured across the land side 414 of the semiconductor package substrate 410. Also as illustrated, the composite and stacked vertical interconnect array 420 is substantially uniformly distributed across the X-Y plane of the of the semiconductor package substrate 410 at the land side 414. By “substantially uniformly distributed” it is meant that an interconnect pitch between any two adjacent composite and stacked vertical interconnects, is within a useful average pitch-deviation standard, beginning at given edge of the semiconductor package substrate 410, and ending at the opposite edge.

In an embodiment, a composite and stacked vertical interconnect 420 contacts the land side 414 of the semiconductor package substrate 410. The composite and stacked vertical interconnect 420 contacts a land-side trace 424 that is part of the semiconductor package substrate 410. In an embodiment, the composite and stacked vertical interconnect 420 contacts the land-side trace 424 near a terminal end 428 of the trace 424. In an embodiment, the land-side trace 424 has a trace length 425.

In an embodiment, the first semiconductive device 436 is face-mounted on the die side 412 by direct contact with interconnects such as the interconnect 416, including an optional solder film (not pictured) where the interconnect 416 communicates to the die side 412 of the semiconductor substrate 410. In an embodiment, an overmolding material 411 contacts the die side 412 and at least partially encapsulates the first semiconductive device 436.

In an embodiment, although only one semiconductive device 436 is depicted, the die side 412 supports two semiconductive devices including the first semiconductive device 434 as face-mounted on the die side 412, and a subsequent semiconductive device that is also face-mounted on the die side 412. For example, the first semiconductive device 436 is face-mounted side-by-side with a subsequent semiconductive device (not illustrated) that is also face-mounted on the die side 412.

In an embodiment, the first semiconductive device 436 is coupled to and supports a subsequent semiconductive device similar to the subsequent semiconductive device 140 depicted in FIG. 1A. In an embodiment, a hanging semiconductive device analogous to the hanging semiconductive device 358 depicted in FIG. 3 is mounted to the land side 414, and the hanging semiconductive device is provided sufficient clearance allowed by the standoff formed by the composite and stacked vertical interconnect 420.

In an embodiment, the composite and stacked vertical interconnect 420 can be quantified in form factor similar to the form-factor parameters described for the reflowed composite and stacked vertical interconnect 121 depicted in FIG. 1D.

In an embodiment, reflow causes some or all the shell solder materials 423 and 427 to blend into the respective core copper materials 422 and 426. In an embodiment, chemical analysis of the composite and stacked vertical interconnect 420 shows a solder-rich and copper-rich zones that are analogous to the solder-rich zone 223′ and the copper-rich zone 222′ depicted in FIG. 2D, where the first core 422 and first shell 423 have partially blended as are depicted in FIG. 4. Similarly in an embodiment, chemical analysis shows solder-rich and copper-rich zones that analogous to the solder-rich zone 227′ and the copper-rich zone 226′ depicted in FIG. 2D, where the second core 426 and second shell 427 also as depicted in FIG. 4 have partially blended.

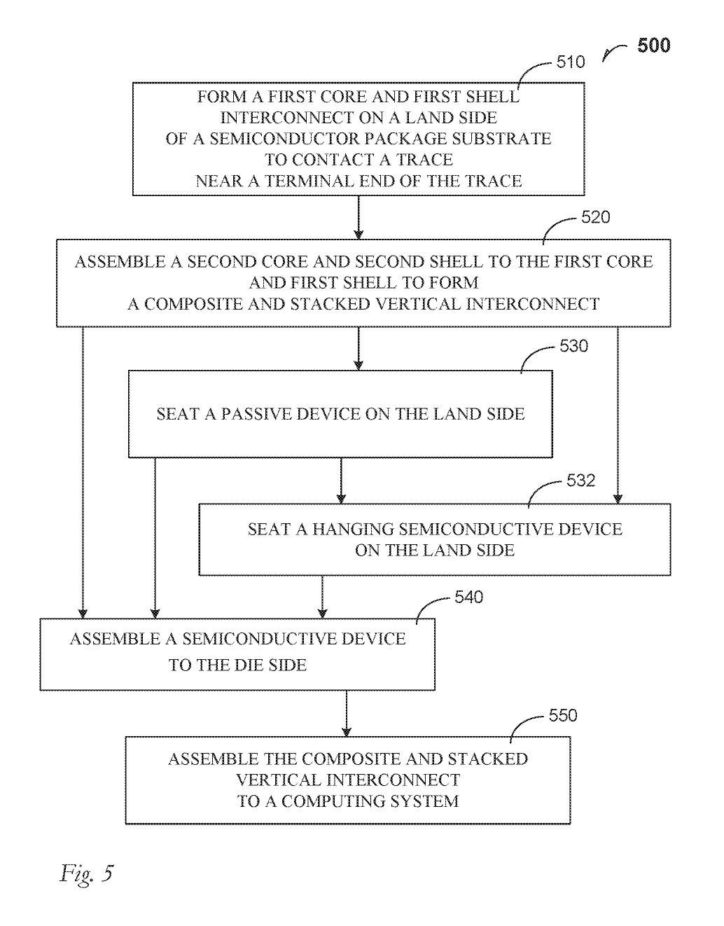

FIG. 5 is a process flow diagram according to several embodiments.

At 510, the process includes forming a first core and first shell interconnect on a land side of a semiconductor package substrate to contact a trace near a terminal end of the trace.

At 520, the process includes assembling a second core and second shell interconnect on the first core and first shell to form a composite and stacked vertical interconnect.

At 530, the process includes seating a passive device on the land side.

At 532, the process includes seating a hanging semiconductive device on the land side.

At 540, the process includes assembling a semiconductive device to the die side of the semiconductor package substrate. The process order of operation 510 to 540 is interchangeable.

At 550, the process includes assembling the composite and stacked vertical interconnect to a computing system.

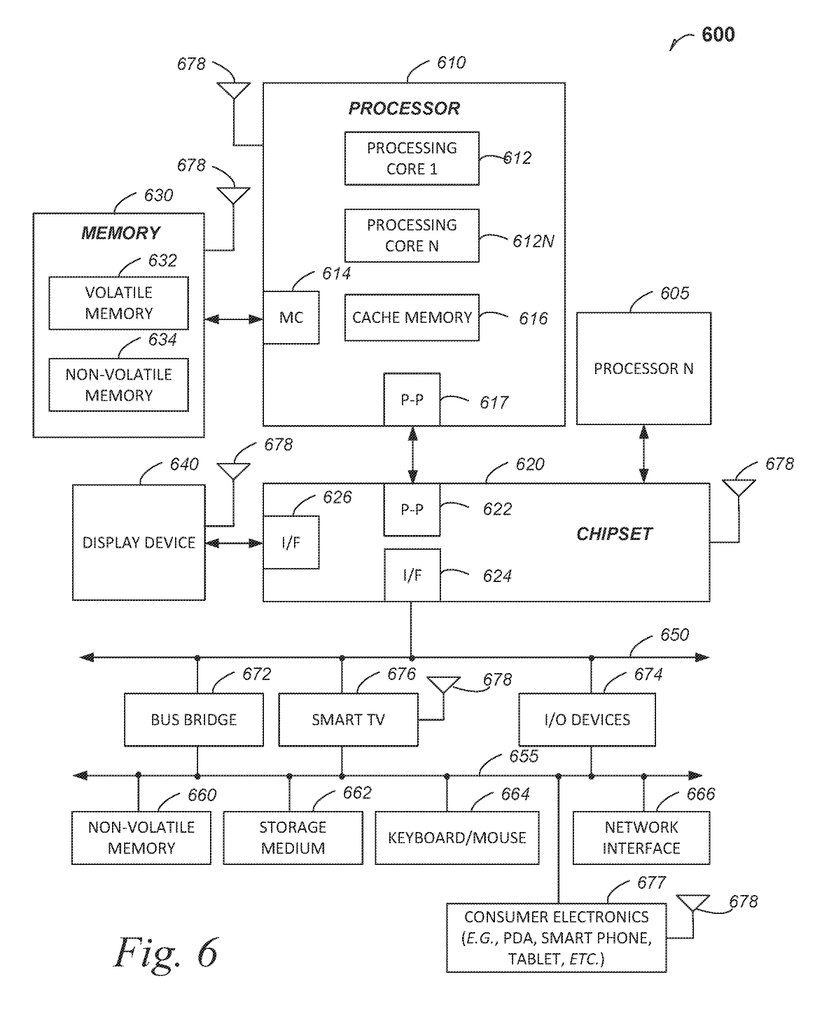

FIG. 6 is included to show an example of a higher-level device application for the disclosed embodiments. The composite and stacked vertical interconnect embodiments may be found in several parts of a computing system. In an embodiment, the composite and stacked vertical interconnect embodiments can be part of a communications apparatus such as is affixed to a cellular communications tower. In an embodiment, a computing system 600 includes, but is not limited to, a desktop computer. In an embodiment, a system 600 includes, but is not limited to a laptop computer. In an embodiment, a system 600 includes, but is not limited to a tablet. In an embodiment, a system 600 includes, but is not limited to a notebook computer. In an embodiment, a system 600 includes, but is not limited to a personal digital assistant (PDA). In an embodiment, a system 600 includes, but is not limited to a server. In an embodiment, a system 600 includes, but is not limited to a workstation. In an embodiment, a system 600 includes, but is not limited to a cellular telephone. In an embodiment, a system 600 includes, but is not limited to a mobile computing device. In an embodiment, a system 600 includes, but is not limited to a smart phone. In an embodiment, a system 600 includes, but is not limited to an internet appliance. In an embodiment, a system 600 includes, but is not limited to a computing system in a motor vehicle. Other types of computing devices may be configured with the microelectronic device that includes composite and stacked vertical interconnect apparatus embodiments.

In an embodiment, the processor 610 has one or more processing cores 612 and 612N, where 612N represents the Nth processor core inside processor 610 where N is a positive integer. In an embodiment, the electronic device system 600 using a composite and stacked vertical interconnect embodiment that includes multiple processors including 610 and 605, where the processor 605 has logic similar or identical to the logic of the processor 610. In an embodiment, the processing core 612 includes, but is not limited to, pre-fetch logic to fetch instructions, decode logic to decode the instructions, execution logic to execute instructions and the like. In an embodiment, the processor 610 has a cache memory 616 to cache at least one of instructions and data for the multi-layer solder resist on a semiconductor device package substrate in the system 600. The cache memory 616 may be organized into a hierarchal structure including one or more levels of cache memory.

In an embodiment, the processor 610 includes a memory controller 614, which is operable to perform functions that enable the processor 610 to access and communicate with memory 630 that includes at least one of a volatile memory 632 and a non-volatile memory 634. In an embodiment, the processor 610 is coupled with memory 630 and chipset 620. In an embodiment, the chipset 620 is part of a composite and stacked vertical interconnect embodiment depicted in any of FIGS. 1-4. The processor 610 may also be coupled to a wireless antenna 678 to communicate with any device configured to at least one of transmit and receive wireless signals. In an embodiment, the wireless antenna interface 678 operates in accordance with, but is not limited to, the IEEE 802.11 standard and its related family, Home Plug AV (HPAV), Ultra Wide Band (UWB), Bluetooth, WiMax, or any form of wireless communication protocol.

In an embodiment, the volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. The non-volatile memory 634 includes, but is not limited to, flash memory, phase change memory (PCM), read-only memory (ROM), electrically erasable programmable read-only memory (EEPROM), cross-point memory or any other type of non-volatile memory device.

The memory 630 stores information and instructions to be executed by the processor 610. In an embodiment, the memory 630 may also store temporary variables or other intermediate information while the processor 610 is executing instructions. In the illustrated embodiment, the chipset 620 connects with processor 610 via Point-to-Point (PtP or P-P) interfaces 617 and 622. Either of these PtP embodiments may be achieved using a composite and stacked vertical interconnect embodiment as set forth in this disclosure. The chipset 620 enables the processor 610 to connect to other elements in a composite and stacked vertical interconnect embodiment in a system 600. In an embodiment, interfaces 617 and 622 operate in accordance with a PtP communication protocol such as the Intel® QuickPath Interconnect (QPI) or the like. In other embodiments, a different interconnect may be used.

In an embodiment, the chipset 620 is operable to communicate with the processor 610, 605N, the display device 640, and other devices 672, 676, 674, 660, 662, 664, 666, 677, etc. The chipset 620 may also be coupled to a wireless antenna 678 to communicate with any device configured to at least do one of transmit and receive wireless signals.

The chipset 620 connects to the display device 640 via the interface 626. The display 640 may be, for example, a liquid crystal display (LCD), a plasma display, cathode ray tube (CRT) display, or any other form of visual display device. In an embodiment, the processor 610 and the chipset 620 are merged into a composite and stacked vertical interconnect embodiment in a system. Additionally, the chipset 620 connects to one or more buses 650 and 655 that interconnect various elements 674, 660, 662, 664, and 666. Buses 650 and 655 may be interconnected together via a bus bridge 672 such as at least one composite and stacked vertical interconnect embodiment. In an embodiment, the chipset 620, via interface 624, couples with a non-volatile memory 660, a mass storage device(s) 662, a keyboard/mouse 664, a network interface 666, smart TV 676, and the consumer electronics 677, etc.

In an embodiment, the mass storage device 662 includes, but is not limited to, a solid-state drive, a hard disk drive, a universal serial bus flash memory drive, or any other form of computer data storage medium. In one embodiment, the network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 6 are depicted as separate blocks within the composite and stacked vertical interconnect embodiments in a computing system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into the processor core 612.

To illustrate the composite and stacked vertical interconnect embodiments and methods disclosed herein, a non-limiting list of examples is provided herein:

Example 1 is a semiconductor package substrate, comprising: a semiconductor device substrate including a die side and a land side; a trace on the land side, wherein the trace is coupled to the die side; a composite and stacked vertical interconnect in contact with the trace near a terminal end, wherein the composite and stacked vertical interconnect includes a first core and a first shell that contact the trace, and a second core and second shell that contact the first core and first shell; and wherein the composite and stacked vertical interconnect has a first characteristic dimension including the first core and first shell, and a second characteristic dimension including the second core and second shell, and wherein the second characteristic dimension is larger than the first characteristic dimension.

In Example 2, the subject matter of Example 1 optionally includes wherein the first core and first shell exhibit a spheroidal form factor, and wherein the second core and second shell exhibit a spheroidal form factor.

In Example 3, the subject matter of any one or more of Examples 1-2 optionally include wherein the first core and first shell exhibit a copper-rich zone and a solder-rich zone, wherein the solder-rich zone is outside the copper-rich zone.

In Example 4, the subject matter of any one or more of Examples 1-3 optionally include wherein the second core and second shell exhibit a copper-rich zone and a solder-rich zone, wherein the solder-rich zone is outside the copper-rich zone.

In Example 5, the subject matter of any one or more of Examples 1-4 optionally include wherein the first core and first shell exhibit a spheroidal form factor, and wherein the second core and second shell exhibit a rectangular form factor.

In Example 6, the subject matter of any one or more of Examples 1-5 optionally include wherein the first core and first shell exhibit a copper-rich zone and a solder-rich zone, wherein the solder-rich zone is outside the copper-rich zone.

In Example 7, the subject matter of any one or more of Examples 1-6 optionally include wherein the second core and second shell exhibit a copper-rich zone and a solder-rich zone, wherein the solder-rich zone is outside the copper-rich zone.

In Example 8, the subject matter of any one or more of Examples 1-7 optionally include wherein the composite and stacked vertical interconnect is one of an array of composite and stacked vertical interconnects that is arrayed on the land side; and a board onto which the array of composite and stacked vertical interconnects is mounted.

In Example 9, the subject matter of any one or more of Examples 1-8 optionally include a semiconductive device disposed on the semiconductor package substrate die side, wherein the semiconductive device is flip-chip bonded to the semiconductor package substrate by an electrical bump from a ball array.

In Example 10, the subject matter of any one or more of Examples 1-9 optionally include a semiconductive device disposed on the semiconductor package substrate die side, wherein the semiconductive device is flip-chip bonded to the semiconductor package substrate by an electrical bump from a ball array, and wherein the composite and stacked vertical interconnect is one of an array of composite and stacked vertical interconnects that is arrayed on the land side; and a board onto which the array of composite and stacked vertical interconnects is mounted.

In Example 11, the subject matter of any one or more of Examples 1-10 optionally include a semiconductive device disposed on the semiconductor package substrate die side, wherein the semiconductive device is face-mounted on the die side by direct contact.

In Example 12, the subject matter of any one or more of Examples 1-11 optionally include a semiconductive device disposed on the semiconductor package substrate die side, wherein the semiconductive device is face-mounted on the die side by direct contact, and wherein the composite and stacked vertical interconnect is one of an array of composite and stacked vertical interconnects that is arrayed on the land side; and a board onto which the array of composite and stacked vertical interconnects is mounted.

In Example 13, the subject matter of any one or more of Examples 1-12 optionally include wherein the first and second cores and shells creates a standoff height, further including a passive device disposed on the land side, wherein the passive device has a thickness that is less than the standoff height.

In Example 14, the subject matter of any one or more of Examples 1-13 optionally include wherein the first and second cores and shells creates a standoff height, further including a passive device disposed on the land side, wherein the passive device has a thickness that is less than the standoff height, wherein the composite and stacked vertical interconnect is one of an array of composite and stacked vertical interconnects that is arrayed on the land side, and wherein the array of composite and stacked vertical interconnects includes an open space to accommodate the passive device; and a board onto which the array of composite and stacked vertical interconnects is mounted.

In Example 15, the subject matter of any one or more of Examples 1-14 optionally include wherein the first and second cores and shells creates a standoff height, further including a hanging semiconductive device disposed on the land side, wherein the hanging semiconductive device has a thickness that is less than the standoff height.

In Example 16, the subject matter of any one or more of Examples 1-15 optionally include wherein the first and second cores and shells creates a standoff height, further including a hanging semiconductive device disposed on the land side, wherein the hanging semiconductive device has a thickness that is less than the standoff height, wherein the composite and stacked vertical interconnect is one of an array of composite and stacked vertical interconnects that is arrayed on the land side, and wherein the array of composite and stacked vertical interconnects includes an open space to accommodate the hanging semiconductive device; and a board onto which the array of composite and stacked vertical interconnects is mounted.

Example 17 is a method of forming a land side interconnect, comprising: forming an interconnect first core and first shell on a trace near a terminal end thereof, wherein the trace is on a land side of a semiconductor package substrate; and contacting an interconnect second core and second shell to the first core and first shell, wherein the first core and first shell has a smaller lateral dimension than the second core and shell.

In Example 18, the subject matter of Example 17 optionally includes seating a passive device on the land side.

In Example 19, the subject matter of any one or more of Examples 17-18 optionally include seating a hanging semiconductive device on the land side.

In Example 20, the subject matter of any one or more of Examples 17-19 optionally include seating a semiconductive device on the semiconductor package substrate on a die side thereof, wherein the die side is opposite the land side.

In Example 21, the subject matter of any one or more of Examples 17-20 optionally include seating a semiconductive device on the semiconductor package substrate on a die side thereof, wherein the die side is opposite the land side, and wherein the semiconductive device is face-mounted on the die side by direct contact.

Example 22 is a computing system, comprising: a semiconductor package substrate including a die side and a land side; a trace on the land side, wherein the trace is coupled to the die side; a composite and stacked vertical interconnect in contact with the trace near a terminal end, wherein the composite and stacked vertical interconnect includes a first core and a first shell that contact the trace, and a second core and second shell that contact the first core and first shell; wherein the composite and stacked vertical interconnect has a first characteristic dimension including the first core and first shell, and a second characteristic dimension including the second core and second shell, and wherein the second characteristic dimension is larger than the first characteristic dimension; a board that is bonded to the second core and second shell; and a chipset coupled to the semiconductive device.

In Example 23, the subject matter of Example 22 optionally includes at least one of a passive device on the land side and a hanging semiconductive device on the land side; and wherein the board includes an external shell that provides at least one of structural and electrical-insulative qualities for the board.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

With semiconductive devices, an “active surface” includes active semiconductive devices and may include metallization that connects to the active semiconductive devices. A “backside surface” is the surface opposite the active surface.

Method examples described herein can be machine or computer-implemented at least in part. Some examples can include a computer-readable medium or machine-readable medium encoded with instructions operable to configure an electrical device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the disclosed embodiments should be determined with reference to the appended claims, along with the full scope of equivalents to which such claims are entitled.

1. A semiconductor package substrate, comprising:
a semiconductor device substrate including a die side and a land side;
a trace on the land side, wherein the trace is coupled to the die side;
a composite and stacked vertical interconnect in contact with the trace near a terminal end, wherein the composite and stacked vertical interconnect includes a first core and a first shell that contact the trace, and a second core and second shell that contact the first core and first shell; and
wherein the composite and stacked vertical interconnect has a first characteristic dimension including the first core and first shell, and a second characteristic dimension including the second core and second shell, and wherein the second characteristic dimension is larger than the first characteristic dimension.

2. The semiconductor package substrate of claim 1, wherein the first core and first shell exhibit a spheroidal form factor, and wherein the second core and second shell exhibit a spheroidal form factor.

3. The semiconductor package substrate of claim 1, wherein the first core and first shell exhibit a copper-rich zone and a solder-rich zone, wherein the solder-rich zone is outside the copper-rich zone.

4. The semiconductor package substrate of claim 1, wherein the second core and second shell exhibit a copper-rich zone and a solder-rich zone, wherein the solder-rich zone is outside the copper-rich zone.

5. The semiconductor package substrate of claim 1, wherein the first core and first shell exhibit a spheroidal form factor, and wherein the second core and second shell exhibit a rectangular form factor.

6. The semiconductor package substrate of claim 1, wherein the first core and first shell exhibit a copper-rich zone and a solder-rich zone, wherein the solder-rich zone is outside the copper-rich zone.

7. The semiconductor package substrate of claim 1, wherein the second core and second shell exhibit a copper-rich zone and a solder-rich zone, wherein the solder-rich zone is outside the copper-rich zone.

8. The semiconductor package substrate of claim 1, wherein the composite and stacked vertical interconnect is one of an array of composite and stacked vertical interconnects that is arrayed on the land side; and
a board onto which the array of composite and stacked vertical interconnects is mounted.

9. The semiconductor package substrate of claim 1, further including a semiconductive device disposed on the semiconductor package substrate die side, wherein the semiconductive device is flip-chip bonded to the semiconductor package substrate by an electrical bump from a ball array.

10. The semiconductor package substrate of claim 1, further including a semiconductive device disposed on the semiconductor package substrate die side, wherein the semiconductive device is flip-chip bonded to the semiconductor package substrate by an electrical bump from a ball array, and wherein the composite and stacked vertical interconnect is one of an array of composite and stacked vertical interconnects that is arrayed on the land side, and
a board onto which the array of composite and stacked vertical interconnects is mounted.

11. The semiconductor package substrate of claim 1, further including a semiconductive device disposed on the semiconductor package substrate die side, wherein the semiconductive device is face-mounted on the die side by direct contact.

12. The semiconductor package substrate of claim 1, further including a semiconductive device disposed on the semiconductor package substrate die side, wherein the semiconductive device is face-mounted on the die side by direct contact, and wherein the composite and stacked vertical interconnect is one of an array of composite and stacked vertical interconnects that is arrayed on the land side; and
a board onto which the array of composite and stacked vertical interconnects is mounted.

13. The semiconductor package substrate of claim 1, wherein the first and second cores and shells creates a standoff height, further including a passive device disposed on the land side, wherein the passive device has a thickness that is less than the standoff height.

14. The semiconductor package substrate of claim 1, wherein the first and second cores and shells creates a standoff height, further including a passive device disposed on the land side, wherein the passive device has a thickness that is less than the standoff height, wherein the composite and stacked vertical interconnect is one of an array of composite and stacked vertical interconnects that is arrayed on the land side, and wherein the array of composite and stacked vertical interconnects includes an open space to accommodate the passive device; and
a board onto which the array of composite and stacked vertical interconnects is mounted.

15. The semiconductor package substrate of claim 1, wherein the first and second cores and shells creates a standoff height, further including a hanging semiconductive device disposed on the land side, wherein the hanging semiconductive device has a thickness that is less than the standoff height.

16. The semiconductor package substrate of claim 1, wherein the first and second cores and shells creates a standoff height, further including a hanging semiconductive device disposed on the land side, wherein the hanging semiconductive device has a thickness that is less than the standoff height, wherein the composite and stacked vertical interconnect is one of an array of composite and stacked vertical interconnects that is arrayed on the land side, and wherein the array of composite and stacked vertical interconnects includes an open space to accommodate the hanging semiconductive device; and
a board onto which the array of composite and stacked vertical interconnects is mounted.

17. A method of forming a land side interconnect, comprising:
forming an interconnect first core and first shell on a trace near a terminal end thereof, wherein the trace is on a land side of a semiconductor package substrate; and
contacting an interconnect second core and second shell to the first core and first shell, wherein the first core and first shell has a smaller lateral dimension than the second core and shell.

18. The method of claim 17, further including seating a passive device on the land side.

19. The method of claim 17, further including seating a hanging semiconductive device on the land side.

20. The method of claim 17, further including seating a semiconductive device on the semiconductor package substrate on a die side thereof, wherein the die side is opposite the land side.

21. The method of claim 17, further including seating a semiconductive device on the semiconductor package substrate on a die side thereof, wherein the die side is opposite the land side, and wherein the semiconductive device is face-mounted on the die side by direct contact.

22. A computing system, comprising:
a semiconductor package substrate including a die side and a land side:
a trace on the land side, wherein the trace is coupled to the die side;
a composite and stacked vertical interconnect in contact with the trace near a terminal end, wherein the composite and stacked vertical interconnect includes a first core and a first shell that contact the trace, and a second core and second shell that contact the first core and first shell;
wherein the composite and stacked vertical interconnect has a first characteristic dimension including the first core and first shell, and a second characteristic dimension including the second core and second shell, and wherein the second characteristic dimension is larger than the first characteristic dimension;
a board that is bonded to the second core and second shell; and
a chipset coupled to the semiconductive device.

23. The computing system of claim 22, further including:
at least one of a passive device on the land side and a hanging semiconductive device on the land side; and
wherein the board includes an external shell that provides at least one of structural and electrical-insulative qualities for the board.
